(19) United States
(12) Patent Application Publication
(10) Pub. No.: US 2026/0341594 A1
(43) Pub. Date: Oct. 29, 2026

(54) Feedthrough Filter Assembly Containing A Solder Film

(71) Applicant: KYOCERA AVX Components Corporation, Fountain Inn, SC (US)

(72) Inventors: Matthew Tenuto, Greenville, SC (US); John Galvagni, Hendersonville, NC (US)

(21) Appl. No.: 19/549,049

(22) Filed: Feb. 25, 2026

Related U.S. Application Data
(60) Provisional application No. 63/764,596, filed on Feb. 28, 2025.

(51) Int. Cl. H01G 2/02; H01G 4/232; H01G 4/242; H01G 4/30; H01G 4/35; H03H 1/00

(52) U.S. Cl. CPC H01G 2/02; H01G 4/232; H01G 4/242; H01G 4/30; H01G 4/35; H03H 1/00; H03H 2001/0042

(57) ABSTRACT

A feedthrough filter assembly is disclosed. The feedthrough filter assembly includes a feedthrough filter capacitor, a conductive ferrule, a solder film, and a conductive terminal pin. The feedthrough filter capacitor includes first and second sets of electrode plates, a passageway therethrough having a first termination surface conductively coupling the first set of electrode plates, and a second termination surface exteriorly coupling the second set of electrode plates. The conductive ferrule is adjacent to the feedthrough filter capacitor. The solder film includes solder and a film-forming flux, wherein the solder film conductively couples at least a portion of the second termination surface of the feedthrough filter capacitor to the ferrule. The conductive terminal pin extends through the passageway in conductive relation with the first set of electrode plates, and through the ferrule in non-conductive relation.

### RELATED APPLICATION

The present application is based upon and claims priority to U.S. Provisional Patent Application Ser. No. 63/764,596, having a filing date of Feb. 28, 2025, which is incorporated in its entirety herein by reference.

### BACKGROUND OF THE INVENTION

Feedthrough filter assemblies are commonly used to pass electrical signals through a barrier while still maintaining the physical and environmental integrity of the barrier. For instance, feedthrough filter assemblies are commonly used in electrical medical devices, such as pacemakers, defibrillators, and ECG machines, as many medical devices must meet strict electromagnetic interference (EMI) and electromagnetic compatibility (EMC) standards. Such feedthrough filter assemblies often include a feedthrough filter capacitor, such as a multilayer ceramic capacitor, that helps filter any unwanted EMI. Feedthrough filter assemblies often also comprise a ferrule, which is an electrically conductive material that is coupled to the container of the device in which it is used, a conductive terminal pin that extends through a cavity of the ferrule, and a sealing element that forms a hermetic seal between the ferrule and the terminal pin so that no bodily fluids or other unwanted substances enter the feedthrough filter assembly. The feedthrough filter capacitor electrically contacts the conductive terminal pin and the ferrule. Thus, by utilizing the feedthrough filter capacitor within the feedthrough filter assembly, any unwanted EMI is dissipated at the entrance of the medical device.

Despite the benefits of employing a feedthrough filter capacitor in a feedthrough filter assembly, the methods of manufacture and installation of such assemblies leave much to be desired. For instance, known methods of manufacture and installation can not only be costly, but also imprecise, which may inhibit performance of the filter capacitor assembly. Standard soldering approaches lack precision, as it is often difficult to ensure that enough solder is applied in the precise locations where soldering needs to occur. Another known method of installation is to utilize a solid preform. Although the use of the solid preform may be considered advantageous because it is easy to control both the amount of solder applied and the placement of the preform within the feedthrough filter assembly, many problems may still remain such as uneven flux distribution. Further, without sufficient and uniform heat, the solid preform may recede, which can result in gaps along the circumference, which in turn can reduce the insertion loss, and fail the part.

As such, a need currently exists for improved methods to install filter capacitor assemblies in electrical feedthroughs.

### SUMMARY OF THE INVENTION

In accordance with one embodiment of the present invention, a feedthrough filter assembly including a feedthrough filter capacitor, a conductive ferrule, a solder film, and a conductive terminal pin is disclosed. The feedthrough filter capacitor includes first and second sets of electrode plates, a passageway therethrough having a first termination surface conductively coupling the first set of electrode plates, and a second termination surface exteriorly coupling the second set of electrode plates. The conductive ferrule is adjacent to the feedthrough filter capacitor. The solder film comprises solder and a film-forming flux, wherein the solder film conductively couples at least a portion of the second termination surface of the feedthrough filter capacitor to the ferrule. The conductive terminal pin extends through the passageway in conductive relation with the first set of electrode plates and through the ferrule in non-conductive relation.

In accordance with another embodiment of the present invention, a method for forming a feedthrough filter assembly is disclosed. The method includes disposing a filter feedthrough capacitor within a conductive ferrule. The capacitor includes first and second sets of electrode plates, a passageway therethrough having a first termination surface conductively coupling the first set of electrode plates, and a second termination surface exteriorly coupling the second set of electrode plates. The method also includes disposing a solder film comprising a solder and a film-forming flux in contact with the filter feedthrough capacitor and conductive ferrule, and conductively coupling the second termination surface of the filter feedthrough capacitor and the conductive ferrule.

Other features and aspects of the present invention are set forth in greater detail below.

### BRIEF DESCRIPTION OF THE FIGURES

A full and enabling disclosure of the present invention to one skilled in the art, including the best mode thereof, is set forth more particularly in the remainder of the specification, including reference to the accompanying figures, in which:

FIG. 1 is a cross-sectional view of one embodiment of a feedthrough filter assembly of the present invention;

FIG. 2 is a cross-sectional view of one embodiment of a feedthrough filter assembly of the present invention;

FIG. 3 is a cross-sectional view of one embodiment of a feedthrough filter assembly of the present invention;

FIG. 4 is a cross-sectional view of one embodiment of a feedthrough filter assembly of the present invention;

FIG. 5 is a cross-sectional view of one embodiment of a feedthrough filter capacitor of the present invention; and

FIG. 6 is a perspective view of one embodiment of a feedthrough filter capacitor of the present invention.

Repeat use of reference characters in the present specification and in different figures is intended to represent the same or analogous features or elements.

### DETAILED DESCRIPTION

It is to be understood by one of ordinary skill in the art that the present discussion is a description of exemplary embodiments only and is not intended as limiting the broader aspects of the present invention.

Generally speaking, the present disclosure is directed to a feedthrough filter assembly including a feedthrough filter capacitor, a conductive ferrule, a solder film, and a conductive terminal pin. The feedthrough filter capacitor includes first and second sets of electrode plates, a passageway therethrough having a first termination surface conductively coupling the first set of electrode plates, and a second termination surface exteriorly coupling the second set of electrode plates. The conductive ferrule is adjacent to the feedthrough filter capacitor. The solder film comprises solder and a film-forming flux, wherein the solder film conductively couples at least a portion of the second termination surface of the feedthrough filter capacitor to the ferrule. The conductive terminal pin extends through the passageway in conductive relation with the first set of electrode plates and through the ferrule in non-conductive relation.

Conventionally, known methods of conductively coupling a capacitor to a ferrule have presented many challenges. For instance, solid preforms have been utilized to conductively couple the capacitor. Although the use of a solid preform to couple a capacitor to a ferrule allows for easy application and control of the exact amount of solder applied, the use of a solid preform may result in uneven solder distribution in the event of insufficient or nonuniform heating. Whereas, although the use of a solder paste to conductively couple the capacitor allows for precise placement of the solder, it is often very difficult, time consuming, or expensive to apply. Without intending to be limited by theory, the present inventors have discovered that selective control and formation of the films (e.g. “solder films”) may result in a means to conductively couple the capacitor to the ferrule with the precision and uniformity of a solder paste but also with the ease of application of a solid preform. Thus, the film may result in improvements in the conductive coupling of the capacitor, even under unreliable heating conditions or when solder gaps are present.

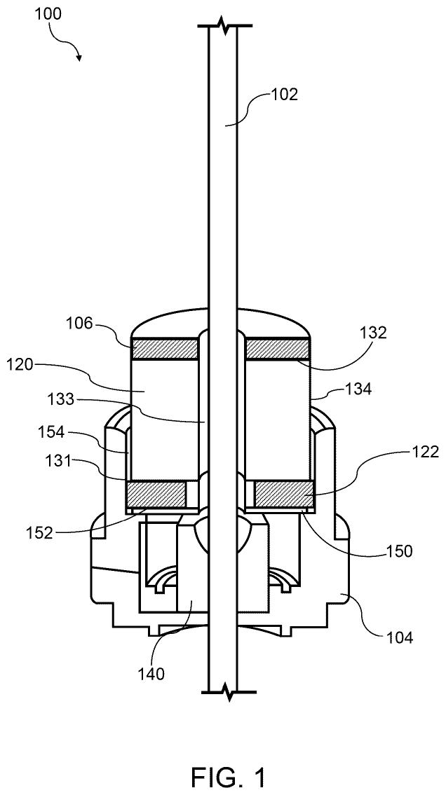

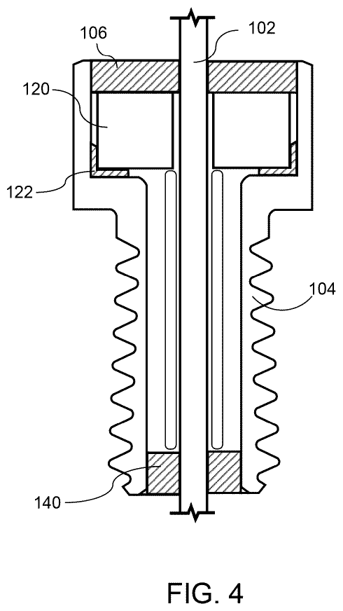

Feedthrough filter assemblies are generally well known in the art for connecting electrical signals through the housing of an electronic instrument. Referring now to FIGS. 1-4, the feedthrough filter assembly 100 of the present disclosure includes a feedthrough filter capacitor 120, a conductive ferrule 104, a conductive terminal pin 102, a solder film 122, and a central bore 154. The feedthrough filter capacitor 120 has a bottom surface 131, an opposing top surface 132, a passageway therethrough having a first termination surface 133, and a second termination surface 134.

The feedthrough filter assembly 100 of the present disclosure includes a ferrule 104 adjacent to the feedthrough filter capacitor 120 and conductively coupled to at least a portion of the second termination surface 134 of the feedthrough filter capacitor 120, so that the ferrule 104 is electrically connected to at least a portion of the perimeter edge at an outer periphery of the capacitor 120 via the film 122.

In general, the ferrule 104 is made from an electrically conductive metal. For instance, the ferrule can be made from titanium, niobium, aluminum, stainless steel, zirconium, tantalum, nickel, or alloys thereof. In certain embodiments, the ferrule 104 is made from a biocompatible material, such as a biocompatible electrically conductive material. Thus, in certain example embodiments, the biocompatible electrically conductive material comprises titanium, niobium, aluminum, stainless steel, zirconium, tantalum, nickel, or an alloy thereof.

In other embodiments, such as in non-medical applications, the ferrule 104 can include other base materials, such as Kovar (e.g., a nickel-cobalt-iron alloy), stainless steel, copper and copper alloys, tungsten, molybdenum, Ivnar (e.g., a nickel-iron alloy), and other various polymers as known in the art, such as glass-filled polymers. It should be understood that the ferrule may be made of any material compatible with the feedthrough filter assembly's desired application (e.g., industrial, electrical, mechanical, medical, etc.).

In some embodiments, the ferrule 104 is generally cylindrical in shape. The ferrule 104 may generally define a bore 154 that is configured to surround the capacitor 120, the conductive terminal pin 102, an insulator 140, and an optional support structure 150. The bore 154 of the ferrule defines an inner surface of the ferrule 104 that is conductively coupled to at least a portion of the second termination surface 134 of the capacitor 120 via the solder film 122. For instance, the ferrule 104 may be conductively coupled to the ground electrode layers of the capacitor.

In some embodiments, a portion of the bottom surface 131 of the capacitor 120 may also be substantially flush with the film 122 and a surface of the ferrule 104. As used herein, the term “substantially flush” means that about 50% or greater of the surface area of the bottom surface 131 is flush with a surface of the ferrule 104, such as about 60% or greater, such as about 70% or greater, such as about 80% or greater, such as about 90% or greater. In other embodiments, at least one support structure 150 is configured inside of the ferrule 104 and contacts at least a portion of the bottom surface 131 of the capacitor 120. The support structure 150 may, in some embodiments, include a bottom surface (not shown) and a top surface 152, wherein the top surface 152 of the support structure 150 contacts at least a portion of the bottom surface 131 of the capacitor 120 and/or the film 122. The support structure 150 may also include a perimeter edge that is configured to be flush or mechanically coupled to the inner surface of the bore 154 extending through the ferrule 104. In addition, as described above, the capacitor 120 will have a top surface 132. In certain embodiments, a sealing material is placed adjacent to the top surface 132 so that no unwanted body fluids or other environmental factors (e.g., dust, dirt, debris) may interfere with the electrical connection of the conductive terminal pins 102 and the first set of electrode plates 161 of the capacitor 120 at the first termination surface 133.

In some embodiments, the support structure 150 is made of a non-conductive material, including, but not limited to, polyimide (PI), polyetheretherketone (PEEK), polytetrafluoroethylene (PTFE), polycarbonate (PC), polyvinyl chloride (PVC), polypropylene (PP), polyethylene (PE), acrylic (PMMA), nylon (PA), silicone, or a combination thereof. The support structure 150 may be placed within the ferrule 104 to selectively position the capacitor 120.

The solder film 122 is placed to conductively couple the capacitor 120 to the inner surface 156 of the bore 154 extending through the ferrule 104. The solder film or films as described herein include a solder and a film-forming flux. As demonstrated by FIGS. 1-4, the film 122 conductively couples at least a portion of the second termination surface 134 of the capacitor 120 to the ferrule 104.

The film 122 may include any conventional solder as known in the art. For instance, the film may include one or more types of metals or metal alloys dispersed within the film-forming flux. The metal or metal alloy, in certain embodiments, may be in the form of a powder before it is dispersed within the film-forming flux. The solder powder, in certain embodiments, comprises tin, lead, silver, copper, or an alloy thereof. For instance, the powder may include a lead-based solder such as Tin-Lead (e.g., Sn₆₃Pb₃₇, Sn₆₀Pb₄₀). In some example embodiments, the powder may include low-melting alloys, such as indium-based alloys (e.g., Sn—In, In—Sn—Bi, Sn—Bi—In), lead-free high temperature alloys (Au₈₀Sn₂₀), and conductive adhesives with additives, such as silver or nickel.

In certain embodiments, the powder may include a lead-free solder powder. Suitable lead-free solder powders include tin-silver-copper (e.g., “SAC”) solders (e.g., “SAC305” Sn_{96.5}Ag_{3.0}Cu_{0.5}, “SAC387” Sn_{95.5}Ag_{3.8}Cu_{0.7}), Tin-Copper solders (e.g., Sn_{99.3}Cu_{0.7}), Tin-Silver solders (e.g., Sn_{96.5}Ag_{3.5}), Tin-Bismuth solders (e.g., Sn₄₂Bi₅₈), Tin-Zinc solders (e.g., Sn₉₁Zn₉), Tin-Gold solders (e.g., Au₈₀Sn₂₀) and Tin-Antimony solders (e.g., Sn₉₅Sb₅). Of course, it should be understood by one of ordinary skill in the art that any lead-free solder powder may be utilized within the solder film, including but not limited to those listed above and any further alloy obtained by adding Ag, Cu, In, Ni, Co, Sb, Ge, P, Fe, Zn, Ga or the like to the compositions listed above.

The film includes the solder, such as the solder powder, distributed within a film-forming flux. Film-forming fluxes, aside from being a medium to distribute the solder, may also provide multiple other benefits to the resulting feedthrough filter assembly. For instance, film-forming fluxes may function as a reducing agent that helps prevent oxidation during soldering. The film-forming flux may react with and remove oxidation from the metal surfaces, essentially “reducing” the metal oxide and allowing for better adhesion of the solder. The film-forming flux may also function as a wetting agent. In some embodiments, the film-forming flux “wets” the surface of the metal as it actively reduces the surface tension of the molten solder, which allows for the film-forming flux to move easily and thoroughly over the metal surfaces being joined, thus promoting stronger conductive coupling. Additionally, in some embodiments, the film-forming flux may demonstrate properties that act as corrosion inhibitors. Of course, it should be understood by one of ordinary skill in the art that the specific composition of the film-forming flux utilized will determine its functionality.

In certain embodiments, the film-forming flux may be a solder flux. Generally, a solder flux is a substance or mixture used to promote fusion, such as the fusions of metals or minerals that occurs during the conductive coupling of metal surfaces with a solder or solder alloy. Any suitable flux may be utilized, including, but not limited to, a water-soluble flux, rosin-based flux, no-clean flux, inorganic flux, gel-based flux, wax-based flux, or a combination thereof. In certain embodiments, the film-forming flux may have a solid or a semi-solid consistency, such that they are considered a solid flux.

The film-forming flux of the present disclosure may generally have a variety of characteristics that allows the resulting solder film to be relatively applied to the feedthrough capacitor and ferrule. For example, the film-forming flux typically has a relatively low melting temperature and/or softening temperature (depending on the particular material), but nevertheless remains a solid or semi-solid at room temperature. In some embodiments, for example, the melting temperature and/or softening temperature of the film-forming flux is from about 20 °C to about 100 °C, in some embodiments from about 25 °C to about 95 °C, in some embodiments from about 30 °C to about 90 °C, in some embodiments from about 35 °C to about 70 °C, and in some embodiments, from about 50 °C to about 70 °C. In addition to exhibiting a low melting and/or softening temperature, the film-forming flux nevertheless has a boiling point and/or degradation temperature that is higher than the solder reflow temperature, which typically ranges from about 170 °C to about 350 °C depending on the type of solder. Thus, for instance, the film-forming flux typically has a boiling point temperature and/or degradation temperature of about 250 °C or more, in some embodiments about 300 °C or more, in some embodiments about 320 °C or more, and in some embodiments, from about 360 °C to about 800 °C.

Although by no means required, the film-forming flux, as well as the resulting solder film, may also be substantially free of halogens (e.g., fluorine, chlorine, bromine, etc.) in certain embodiments. For example, halogens may be present in an amount of about 5,000 ppm or less, such as about 4,500 ppm or less, such as about 4,000 ppm or less, such as about 3,500 ppm or less, such as about 3,000 ppm or less, such as about 2,500 ppm or less, such as about 2,000 ppm or less, such as about 1,500 ppm or less, such as about 1,000 ppm or less, such as about 900 ppm or less, such as about 500 ppm or less, such as about 250 ppm or less, and in certain embodiments, in an amount of about 0 ppm.

Any of a variety of film-forming fluxes may be employed that have the desired characteristics as noted above. Suitable film-forming fluxes may include, for instance, resinous fluxes that contain an organic resin (e.g., rosins, waxes, etc.) and/or inorganic resin. Rosin fluxes, for example, contain rosin, which is an organic resin extracted from a raw tree sap or a derivative thereof (e.g., purified rosin hydrogenated rosin, disproportionated rosin, polymerized rosin, carboxylic acid-modified product (e.g., an acrylated rosin, a maleated rosin, a fumarated rosin), etc.). Wax-based fluxes, on the other hand, typically contain a natural or synthetic wax, such as paraffin wax, microcrystalline wax, beeswax, carnauba wax, etc., as well as combinations thereof. If desired, such fluxes may contain the organic and/or inorganic resin as a base component in addition to various other additives. The film-forming fluxes may also be acid-based fluxes that contain or are derived from organic and/or inorganic acids as a base component. Organic acid fluxes may, for example, include an organic acid such as citric acid, succinic acid, lactic acid, adipic acid, and gluconic acid, an optional surfactant, an optional water-soluble solvent, and an activator. Inorganic acid fluxes may likewise include inorganic acids (or salts thereof) such as hydrochloric acid, hydrofluoric acid, stannous chloride, sodium or potassium fluoride, zinc chloride, etc., as well as combinations thereof. The film-forming flux may also contain a combination of acid and resinous materials. Gel-based fluxes, for instance, may include a base component including a rosin or an organic acid, as described above.

In addition to the base component (e.g., resinous material and/or acids (or salts thereof)), the film-forming flux may also include one or more additional additives as are well known in the art, such as activators, solvents, stabilizers, surfactants, antioxidants, tackifiers, plasticizers, dyes, wetting agents, surfactants, thickeners, etc. Activators, for instance, may include chemical compounds added to a flux that actively remove oxide layers from metal surfaces. Suitable activators include, but are not limited to, an organic acid activator, an amine activator, an amine hydrohalogenic acid salt activator, an organic halogen compound activator, or a combination thereof. For instance, organic acid activators include, but are not limited to, adipic acid, azelaic acid, eicosandioic acid, citric acid, glycolic acid, succinic acid, salicylic acid, diglycolic acid, dipicolinic acid, dibutylaniline diglycolic acid, suberic acid, sebacic acid, thioglycol acid, terephthalic acid, dodecanedioic acid, parahydroxyphenylacetic acid, picolinic acid, phenylsuccinic acid, phthalic acid, fumaric acid, maleic acid, malonic acid, lauric acid, benzoic acid, tartaric acid, tris(2-carboxyethyl) isocyanurate, glycine, 1,3-cyclohexanedicarboxylic acid, 2,2-bis(hydroxymethyl)propionic acid, 2,2-bis(hydroxymethyl) butanoic acid, 2,3-dihydroxybenzoic acid, 2,4-diethylglutaric acid, 2-quinolinecarboxylic acid, 3-hydroxybenzoic acid, malic acid, p-anisic acid, stearic acid, 12-hydroxystearic acid, oleic acid, linoleic acid, linolenic acid, dimer acid, hydrogenated dimer acid, trimer acid, hydrogenated trimer acid, or a combination thereof. Amine activators include, but are not limited to, an aliphatic amine, an aromatic amine, an amino alcohol, an imidazole, a benzotriazole, an amino acid, a guanidine, a hydrazide, or a combination thereof. Aliphatic amines can include, but are not limited to, dimethylamine, ethylamine, 1-aminopropane, isopropylamine, trimethylamine, allylamine, n-butylamine, diethylamine, sec-butylamine, tert-butylamine, N,N-dimethylethylamine, isobutylamine, cyclohexylamine, or a combination thereof.

Examples of the aromatic amine can include, but are not limited to, aniline, N-methylaniline, diphenylamine, N-isopropylaniline, and p-isopropylaniline. Examples of the amino alcohol can include 2-aminoethanol, 2-(ethylamino)ethanol, diethanolamine, diisopropanolamine, triethanolamine, N-butyldiethanolamine, triisopropanolamine, N,N-bis(2-hydroxyethyl)-N-cyclohexylamine, N,N,N′,N′-tetrakis-(2-hydroxypropyl)ethylenediamine, N,N,N′,N″,N″-pentakis(2-hydroxypropyl)diethylenetriamine, or a combination thereof.

Examples of the imidazole can include, but are not limited to, 2-methylimidazole, 2-undecylimidazole, 2-heptadecylimidazole, 1,2-dimethylimidazole, 2-ethyl-4-methylimidazole, 2-phenylimidazole, 2-phenyl-4-methylimidazole, 1-benzyl-2-methylimidazole, 1-benzyl-2-phenylimidazole, 1-cyanoethyl-2-methylimidazole, 1-cyanoethyl-2-undecylimidazole, 1-cyanoethyl-2-ethyl-4-methylimidazole, 1-cyanoethyl-2-phenylimidazole, 1-cyanoethyl-2-undecylimidazolium trimellitate, 1-cyanoethyl-2-phenylimidazolium trimellitate, 2,4-diamino-6-[2′-methylimidazolyl-(1′)]-ethyl-s-triazine, 2,4-diamino-6-[2′-undecylimidazolyl-(1′)]-ethyl-s-triazine, 2,4-diamino-6-[2′-ethyl-4′-methylimidazolyl-(1′)]-ethyl-s-triazine, a 2,4-diamino-6-[2′-methylimidazolyl-(1′)]-ethyl-s-triazineisocyanuric acid adduct, a 2-phenylimidazoleisocyanuric acid adduct, 2-phenyl-4,5-dihydroxymethylimidazole, 2-phenyl-4-methyl-5-hydroxymethylimidazole, 2,3-dihydro-1H-pyrrolo[1,2-a]benzimidazole, 1-dodecyl-2-methyl-3-benzylimidazolium chloride, 2-methylimidazoline, 2-phenylimidazoline, 2,4-diamino-6-vinyl-s-triazine, a 2,4-diamino-6-vinyl-s-triazineisocyanuric acid adduct, 2,4-diamino-6-methacryloyloxyethyl-s-triazine, an epoxyimidazole adduct, 2-methylbenzimidazole, 2-octylbenzimidazole, 2-pentylbenzoimidazole, 2-(1-ethylpentyl)benzimidazole, 2-nonylbenzimidazole, 2-(4-thiazolyl)benzimidazole, benzimidazole, or a combination thereof.

Examples of the benzotriazole can include, but are not limited to, 2-(2′-hydroxy-5′-methylphenyl)benzotriazole, 2-(2′-hydroxy-3′-tert-butyl-5′-methylphenyl)-5-chlorobenzotriazole, 2-(2′-hydroxy-3′,5′-di-tert-amylphenyl)benzotriazole, 2-(2′-hydroxy-5′-tert-octylphenyl)benzotriazole, 2,2′-methylenebis[6-(2H-benzotriazol-2-yl)-4-tert-octylphenol], 6-(2-benzotriazolyl)-4-tert-octyl-6′-tert-butyl-4′-methyl-2,2′-methylenebisphenol, 1,2,3-benzotriazole, 1-[N,N-bis(2-ethylhexyl)aminomethyl]benzotriazole, carboxybenzotriazole, 1-[N,N-bis(2-ethylhexyl)aminomethyl]methylbenzotriazole, 2,2′-[[(methyl-1H-benzotriazole-1-yl)methyl]imino]bisethanol, a 1,2,3-benzotriazole sodium salt aqueous solution, 1-(1′,2′-dicarboxyethyl)benzotriazole, 1-(2,3-dicarboxypropyl)benzotriazole, 1-[(2-ethylhexylamino)methyl]benzotriazole, 2,6-bis[(1H-benzotriazole-1-yl)methyl]-4-methylphenol, 5-methylbenzotriazole, or a combination thereof.

Suitable amino acids may include alanine, arginine, asparagine, aspartic acid, cysteine hydrochloride, glutamine, glutamic acid, glycine, histidine, isoleucine, leucine, lysine monohydrochloride, methionine, phenylalanine, proline, serine, threonine, tryptophan, tyrosine, valine, β-alanine, γ-aminobutyric acid, δ-aminovaleric acid, ε-aminohexanoic acid, ε-caprolactam, 7-aminoheptanoic acid, or a combination thereof. Examples of the guanidine can include, but are not limited to, carbodihydrazide, malonic acid dihydrazide, succinate dihydrazide, adipic dihydrazide, 1,3-bis(hydrazinocarbonoethyl)-5-isopropylhydrandine, sebacic acid dihydrazide, dodecanedioic acid dihydrazide, 7,11-octadecadien-1,18-dicarbohydrazide, isophthalic dihydrazide, or a combination thereof. Examples of the hydrazide can include, but are not limited to, dicyandiamide, 1,3-diphenylguanidine, 1,3-di-o-tolylguanidine, or a combination thereof.

Amine hydrohalogenic acid salt activators include, but are not limited to, a hydrohalogenic acid salt (salt of HF, HCl, HBr, or HI) of the amine compound described above as the amine activator. Examples of the amine hydrohalogenic acid salt can include, but are not limited to, stearylamine hydrochloride, diethylaniline hydrochloride, diethanolamine hydrochloride, 2-ethylhexylamine hydrobromide, pyridine hydrobromide, isopropylamine hydrobromide, cyclohexylamine hydrobromide, diethylamine hydrobromide, monoethylamine hydrobromide, 1,3-diphenylguanidine hydrobromide, dimethylamine hydrobromide, dimethylamine hydrochloride, rosinamine hydrobromide, 2-ethylhexylamine hydrochloride, isopropylamine hydrochloride, cyclohexylamine hydrochloride, 2-pipecholine hydrobromide, 1,3-diphenylguanidine hydrochloride, dimethylbenzylamine hydrochloride, hydrazine hydrate hydrobromide, dimethylcyclohexylamine hydrochloride, trinonylamine hydrobromide, diethylaniline hydrobromide, 2-diethylaminoethanol hydrobromide, 2-diethylaminoethanol hydrochloride, ammonium chloride, diallylamine hydrochloride, diallylamine hydrobromide, monoethylamine hydrochloride, monoethylamine hydrobromide, diethylamine hydrochloride, triethylamine hydrobromide, triethylamine hydrochloride, hydrazine monohydrochloride, hydrazine dihydrochloride, hydrazine monohydrobromide, hydrazine dihydrobromide, pyridine hydrochloride, aniline hydrobromide, butylamine hydrochloride, hexylamine hydrochloride, n-octylamine hydrochloride, dodecylamine hydrochloride, dimethylcyclohexylamine hydrobromide, ethylenediamine dihydrobromide, rosinamine hydrobromide, 2-phenylimidazole hydrobromide, 4-benzylpyridine hydrobromate, L-glutamic acid hydrochloride, N-methylmorpholine hydrochloride, betaine hydrochloride, 2-pipecholine hydroiodide, cyclohexylamine hydroiodide, 1,3-diphenylguanidine hydrofluorate, diethylamine hydrofluorate, 2-ethylhexylamine hydrofluoride, cyclohexylamine hydrofluoride, ethylamine hydrofluoride, rosinamine hydrofluoride, cyclohexylamine tetrafluoroborate, cyclohexylamine tetrafluoroborate, or a combination thereof.

Organic halogen compound activators include, but are not limited to, trans-2,3-dibromo-2-butene-1,4-diol, 2,3-dibromo-1,4-butanediol, 2,3-dibromo-1-propanol, 2,3-dichloro-1-propanol, 1,1,2,2-tetrabromoethane, 2,2,2-tribromoethanol, pentabromoethane, carbon tetrabromide, 2,2-bis(bromomethyl)-1,3-propanediol, meso-2,3-Dibromo-succinic, chloroalkane, a chlorinated fatty acid ester, n-hexadecyltrimethylammonium bromide, triallyl isocyanurate hexabromide, 2,2-bis[3,5-dibromo-4-(2,3-dibromopropoxy)phenyl]propane, bis[3,5-dibromo-4-(2,3-dibromopropoxy)phenyl]sulfone, ethylenebispentabromobenzene, 2-chloromethyloxirane, HET acid, HET anhydride, brominated bisphenol, or a combination thereof.

It should be understood by one of ordinary skill in the art that varying levels of activator may result in different flux characteristics. For instance, if the activator is present in the flux in higher amounts, it is possible to suppress corrosion of the flux residue after soldering and to reduce insulation resistance. Whereas, if the activator is present in the flux in lower amounts, the presence of the activator may improve the wettability of the flux and the flux's antioxidant characteristics.

Suitable solvents include polar solvents and non-polar solvents. For instance, suitable polar solvents can be both protic and aprotic. Suitable polar protic solvents include, but are not limited to, isopropyl alcohol, ethanol, methanol, butanol, glycerol, methyl alcohol, water, propylene glycol, glycerol, and acetic acid. Suitable polar aprotic solvents include, but are not limited to, acetone and glycol ethers. Suitable glycol ethers include phenyl glycol, hexylene glycol, and hexyl diglycol. Suitable non-polar solvents include, but are not limited to, toluene, limonene, pine resin, and various forms of chlorinated solvents. It should be understood by one of ordinary skill in the art that different solvents may be employed depending on the desired characteristic of the resulting flux.

The solder film of the present disclosure may also be in any conventional shape as known in the art, such as a circular shape, a square shape, a triangular shape, an oval shape, and the like. It should be understood by one of ordinary skill in the art that the shape may be modified to match the portion(s) of the termination of the capacitor that is desired to be conductively coupled with the ferrule. For instance, in certain embodiments, the film has a circular shape, so that it may conductively couple the perimeter edge at an outer periphery of the capacitor to the ferrule.

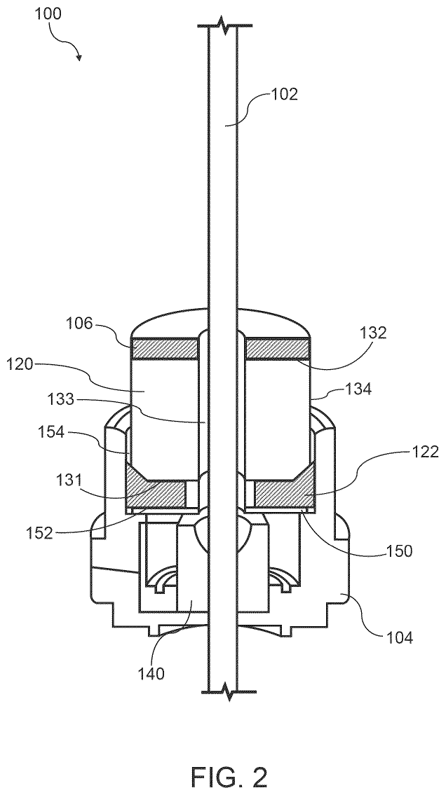

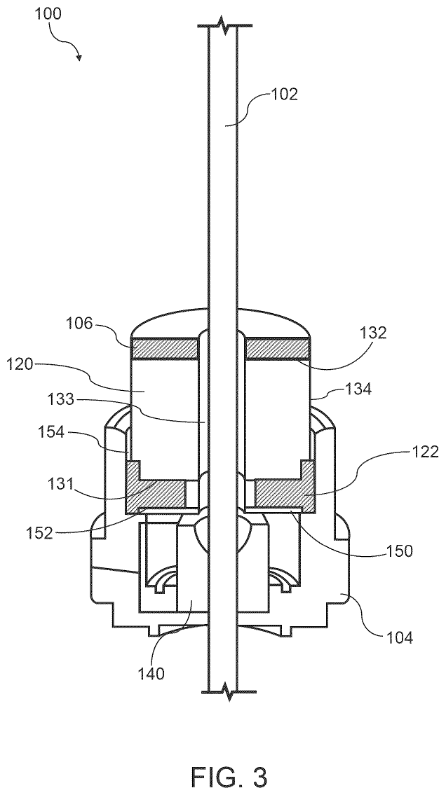

As demonstrated by FIGS. 2-3, the film 122 may also be modified to have alternative cross sections, such as providing a taper that would mate better with the gap between the capacitor 120 and the ferrule 104. Thus, in certain embodiments, the film has one or more tapered sections on the circular shape. As demonstrated by FIG. 2, in some embodiments the tapered sections may generally have a triangular shape. As demonstrated by FIG. 3, in some embodiments the tapered sections may generally have a rectangular shape.

The present disclosure is also generally directed to a method for forming a feedthrough filter assembly. The method includes disposing a filter feedthrough capacitor within a conductive ferrule, wherein the capacitor includes first and second sets of electrode plates, a passageway therethrough having a first termination surface conductively coupling the first set of electrode plates, and a second termination surface exteriorly coupling the second set of electrode plates. The method also includes disposing a solder film comprising a solder and a film-forming flux in contact with the filter feedthrough capacitor and conductive ferrule.

The method further includes heating the solder film at a temperature of about 20 °C to about 100 °C, such as about 25 °C to about 95 °C, such as about 30 °C to about 90 °C, such as about 35 °C to about 70 °C, and in some embodiments, from about 50 °C to about 70 °C to disperse the solder between the second termination surface of the filter feedthrough capacitor and the conductive ferrule. Surprisingly, the present inventors have discovered that the film-forming flux (e.g., wax) melts first, which helps to not only clean the second termination surface of the filter feedthrough capacitor and the surface of the conductive ferrule, but also to protect the solder as it melts and forms a continuous bead of solder around the circumference of the filter feedthrough capacitor.

Although not required, in some embodiments the film-forming flux is removed from the filter feedthrough capacitor surface after the solder film has been heated to disperse the solder between the second termination surface and the filter feedthrough capacitor. Thus, in other embodiments, the film-forming flux is not removed. Without intending to be limited by theory, the present inventors have discovered that keeping the film-forming flux on the surface of the filter feedthrough capacitor may improve the feedthrough filter assembly's resistance to humidity, especially when the feedthrough filter assembly does not employ a hermetic sealing material.

The method further includes conductively coupling the second termination surface of the filter feedthrough capacitor and the conductive ferrule by melting the solder at a temperature that is below the boiling point and/or degradation temperature of the film-forming flux, which is typically 250 °C or more, in some embodiments about 300 °C or more, in some embodiments about 320 °C or more, and in some embodiments, from about 360 °C to about 800 °C. Thus, in certain embodiments, the solder is melted at a temperature of about 170 °C to about 350 °C, such as about 200 °C to about 325 °C, such as about 215 °C to about 275 °C, and in some embodiments, from about 225 °C to about 250 °C. The method further includes extending a conductive terminal pin through the passageway in conductive relation with the first set of electrode plates, and through the conductive ferrule in non-conductive relation.

In certain embodiments, the solder film is formed through a process including mixing a powder (e.g., solder powder), a solvent, and a film-forming flux, as described above, to form a slurry. The process further comprises forming the slurry to a predetermined shape and drying the solvent from the slurry to form the solder film.

Without intending to be limited by theory, the present inventors have discovered that adding a solvent to the powder and the film-forming flux during formation results in a solder film that can be easily manipulated so that it can be easily placed within the feedthrough filter assembly like a solder preform, while still having the potential to have uniform flux distribution and precision of solder placement like a solder paste. The solvent, for instance, can be any conventional solvent as described above. For instance, suitable solvents include polar solvents (both protic and aprotic) and non-polar solvents. Suitable polar protic solvents include, but are not limited to, isopropyl alcohol, ethanol, methanol, butanol, glycerol, methyl alcohol, water, propylene glycol, glycerol, and acetic acid. Suitable polar aprotic solvents include, but are not limited to, acetone and glycol ethers. Suitable glycol ethers include phenyl glycol, hexylene glycol, and hexyl diglycol. Suitable non-polar solvents include, but are not limited to, toluene, limonene, pine resin, and various forms of chlorinated solvents. It should be understood by one of ordinary skill in the art that different solvents may be employed depending on the desired characteristic of the resulting slurry.

In one particular embodiment, isopropyl alcohol is utilized as the solvent. Isopropyl alcohol may evaporate at temperatures as low as 20 °C, as isopropyl alcohol has a relatively high vapor pressure at room temperature. Thus, isopropyl alcohol may be utilized in the production of the solder films of the present disclosure because no additional heating or processing would be needed to evaporate the solvent when desired.

In other embodiments, the solder film is formed by a two-step process of first melting the film-forming flux and then mixing the powder directly into the film-forming flux. Regardless of the method of formation of the solder film, the present inventors have discovered enhanced results when the formation takes place within an inert atmosphere to help prevent oxidation.

The slurry or mixture of the powder, the film-forming flux, and/or the solvent may then be formed to a predetermined shape. As described above, the predetermined shape may be any conventional shape as known in the art, such as a circular shape, so that it may conductively couple the perimeter edge at an outer periphery of the capacitor to the ferrule.

In certain embodiments, the slurry is cast into a mold of the predetermined shape. Any suitable mold may be utilized to form the predetermined shape of the slurry. For instance, the mold may be formed from silicone, polyurethane, latex rubber, epoxy, plaster, metal, or a combination thereof. In other embodiments, the slurry is formed into the desired predetermined shape via screen printing, stenciling, brushing, dip coating, knife coating, spray coating, etc.

Once in the predetermined shape, the solvent is allowed to evaporate from the slurry and/or the film-forming flux is allowed to solidify (e.g., freeze) resulting in the solder film. Thus, in preferred embodiments, the solvent is present in the solder film in an amount of about 15 wt. % or less based on the total weight of the solder film, such as about 10 wt. % or less, such as about 5 wt. % or less, such as about 2.5 wt. % or less, and generally greater than about 0.001 wt. % or more, such as about 0.005 wt. % or more, such as about 0.01 wt. % or more. In certain embodiments, the solvent may entirely evaporate or dry from the solder film, such that the solder film is substantially free of any solvent.

The dried solder film may then be able to be easily manipulated like a “preform” of the predetermined shape, as the solder film includes powder dispersed within the film-forming flux. Thus, once the solvent dries from the slurry, the film has the benefit of a conventional preform, which is easy to apply to the capacitor. Additionally, forming the slurry into a predetermined shape allows for an exact, controlled amount of solder to be utilized.

Once placed within the assembly 100 of the present disclosure, the film 122 is melted and may then demonstrate the advantages of a conventional solder paste, without the difficulty of application. For instance, as demonstrated by FIG. 1-4, the film 122 may be placed within the assembly 100 so that the film 122 is sandwiched between the conductive ferrule 104 and/or an optional support structure 150 and the capacitor 120 so that a portion of the second termination surface 134 of the capacitor 120 is conductively coupled to the inner surface 156 of the bore 154 of the ferrule 104.

The film 122 may be melted at a temperature of about 20 °C or greater, such as about 35 °C or greater, such as about 40 °C or greater, such as about 45 °C or greater, such as about 50 °C or greater, such as about 55 °C or greater, such as about 60 °C or greater, and generally at a temperature of about 100 °C or less, such as about 90 °C or less, such as about 80 °C or less, such as about 70 °C or less, such as about 65 °C or less. Thus, in certain embodiments, the film 122 is melted at a temperature of about 50 °C to about 70 °C, such as from about 55 °C to about 65 °C, such as about 60 °C

The film 122, once melted, would distribute the liquid flux, including the solder, such that it can conductively couple the capacitor 120 and the ferrule 104 in a precise manner through soldering. The solder reflow temperature may be about 170 °C or greater, such as about 180 °C or greater, such as about 190 °C or greater, such as about 200 °C or greater, such as about 210 °C or greater, such as about 220 °C or greater, such as about 230 °C or greater, such as about 240 °C or greater, such as about 250 °C or greater, and generally less than about 350 °C, such as less than about 325 °C, such as less than about 300 °C. It should be understood by one of ordinary skill in the art that the solder reflow temperature depends on the type of solder being used.

The film 122 as disclosed herein can also be utilized in combination with other conductive coupling methods as known in the art. For instance, such coupling may be via a joint, such as a ground joint. Such joint may be a metallized joint (e.g., brazing, welding, etc.) or may be a conductive thermosetting polymer joint. For instance, the solder film described herein may wet and/or bond to a hermetically sealing material, such as a gold brazing. Additionally, the conductive thermosetting polymer may be a polyimide. For instance, such polyimide may include a conductive metal, such as silver for imparting conductivity.

Such coupling, in addition to being conductive, may also be mechanical. In addition, such coupling may provide a gap between a facing surface (e.g., the bottom surface or the opposing top facing surface) of the capacitor, the coupling joint, and/or the insulator. However, in certain embodiments, only the film as described herein is used to conductively couple the capacitor to the ferrule.

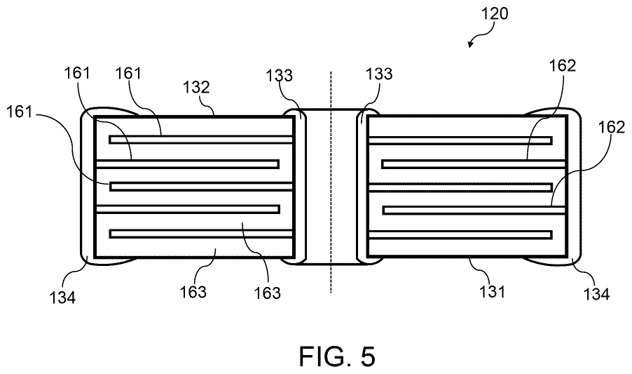

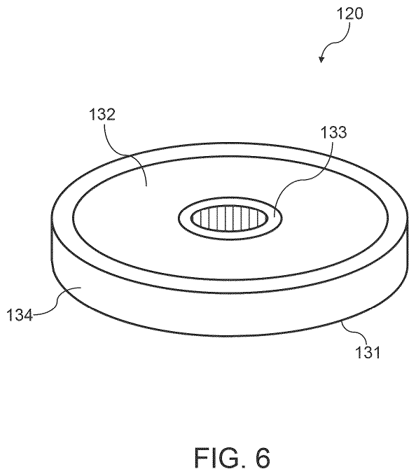

Referring now to FIGS. 1-6, the feedthrough filter capacitor 120 has a bottom surface 131 and an opposing top surface 132. As demonstrated by FIGS. 5-6, the capacitor 120 also includes first and second sets of electrode plates 161, 162, a passageway therethrough having a first termination surface 133 conductively coupling the first set of electrode plates 161, and a second termination surface 134 exteriorly coupling the second set of electrode plates 162.

The capacitor can generally include any type of ceramic capacitor known in the art. For instance, the capacitor may be a multilayer ceramic capacitor containing alternating dielectric layers 163 and electrode plates 161, 162 that are in an alternating and interleaved configuration. In one embodiment, the first set of electrode plates 161 may be referred to as the active electrode layers while the second set of electrode plates 162 may be referred to as the ground electrode layers. The active electrode layers may extend toward an inner diameter cylindrical surface of a passageway of the capacitor. In this regard, the first set of electrode plates 161 may be conductively coupled at a first termination surface 133. Meanwhile, the ground electrode layers may extend toward a perimeter edge at an outer periphery of the capacitor. Such ground electrode layers may be electrically connected by a suitable conductive surface such as a surface metallization layer. In this regard, the set of second electrode plates 162 may be conductively coupled at a second termination surface 134.

In addition to the above, it should be understood that the capacitor of the present invention may include additional electrode layers. For instance, as generally known in the art, the capacitor of the present invention may include anchor electrode layers, shield electrode layers, floating electrode layers, or a combination thereof.

In general, the thickness of the dielectric layers and the electrode layers is not limited and can be any thickness as desired depending on the performance characteristics of the capacitor. For instance, the thickness of the electrode layers can be, but is not limited to, being about 500 nm or greater, such as about 1 μm or greater, such as about 2 μm or greater, such as about 3 μm or greater, such as about 4 μm or greater to about 10 μm or less, such as about 5 μm or less, such as about 4 μm or less, such as about 3 μm or less, such as about 2 μm or less. For instance, the electrode layers may have a thickness of from about 1 μm to about 2 μm. In addition, in one embodiment, the thickness of the dielectric layer may be defined according to the aforementioned thickness of the electrode layers. Also, it should be understood that such thicknesses of the dielectric layers may also apply to the layers between any anchor electrode layers, shield electrode layers, and/or floating electrode layers, when present and as defined herein.

In the capacitors, any dielectric material known in the art may be used for the dielectric layers. For instance, the dielectric layers are typically formed from a material having a relatively high dielectric constant (K), such as from about 10 to about 40,000 in some embodiments from about 50 to about 30,000, and in some embodiments, from about 100 to about 20,000.

In this regard, the dielectric material may be a ceramic. The ceramic may be provided in a variety of forms, such as a wafer (e.g., pre-fired) or a dielectric material that is co-fired within the device itself.

Particular examples of the type of high dielectric material include, for instance, NPO (COG) (up to about 100), X7R (from about 3,000 to about 7,000), X7S, Z5U, and/or Y5V materials. It should be appreciated that the aforementioned materials are described by their industry-accepted definitions, some of which are standard classifications established by the Electronic Industries Alliance (EIA), and as such should be recognized by one of ordinary skill in the art. For instance, such material may include a ceramic. Such materials may include a pervoskite, such as barium titanate and related solid solutions (e.g., barium-strontium titanate, barium calcium titanate, barium zirconate titanate, barium strontium zirconate titanate, barium calcium zirconate titanate, etc.), lead titanate and related solid solutions (e.g., lead zirconate titanate, lead lanthanum zirconate titanate), sodium bismuth titanate, and so forth. In one particular embodiment, for instance, barium strontium titanate (“BSTO”) of the formula BaₓSr₁₋ₓTiO₃ may be employed, wherein x is from 0 to 1, in some embodiments from about 0.15 to about 0.65, and in some embodiments, from about from 0.25 to about 0.6.

In the capacitors, any electrode material known in the art may be employed for the electrodes. For instance, the electrode layers may be formed from any of a variety of different metals as is known in the art. The electrode layers may be made from a metal, such as a conductive metal. The materials may include precious metals (e.g., silver, gold, palladium, platinum, etc.), base metals (e.g., copper, tin, nickel, chrome, titanium, tungsten, etc.), and so forth, as well as various combinations thereof. Sputtered titanium/tungsten (Ti/W) alloys, as well as respective sputtered layers of chrome, nickel, and gold, may also be suitable. The electrodes may also be made of a low resistive material, such as silver, copper, gold, aluminum, palladium, etc. In one particular embodiment, the electrode layers may comprise nickel or an alloy thereof. In another embodiment, the electrode layers may comprise silver or an alloy thereof, such as a silver palladium alloy.

The external terminals, such as the first and second termination surfaces 133, 134, may be formed from any of a variety of different metals as known in the art. The external terminals may be made from a metal, such as a conductive metal. The materials may include precious metals (e.g., silver, gold, palladium, platinum, etc.), base metals (e.g., copper, tin, nickel, chrome, titanium, tungsten, etc.), and so forth, as well as various combinations thereof. In one particular embodiment, the external terminals may comprise copper or an alloy thereof. In another embodiment, they may comprise silver. For instance, such terminal may be formed by a silver polyimide paste that is cured.

The external terminals can be formed using any method generally known in the art. The external terminals may be formed using techniques such as sputtering, painting, printing, electroless plating or fine copper termination (FCT), electroplating, plasma deposition, propellant spray/air brushing, and so forth.

Referring now to FIGS. 1-6, the assembly 100 of the present disclosure also includes a conductive terminal pin 102. The conductive terminal pins 102 are electrically connected to the first set of electrode plates 161 of the capacitor 120 at the first termination surface 133 (e.g., an inner diameter cylindrical surface of the capacitor that defines the passageway), such that the conductive terminal pin 102 extends through the passageway of the capacitor 120 in conductive relation with the first set of electrode plates 161. In certain embodiments, the solder film may be utilized to connect the conductive terminal pin 102 to the first set of electrode plates 161 at the first termination surface 133. In addition, the conductive terminal pin 102 may also extend through the ferrule 104 in a non-conductive relation. The pins may be made from any material generally known in the art. For instance, the pins may be a metal. In particular, the pins may be platinum, gold, titanium, niobium, tantalum, palladium, iridium, alloys thereof or the like. For instance, in one embodiment, the pins may be a single solid alloy material (i.e., no separate core and coatings). In particular, the pins may be a palladium/iridium alloy. For instance, the alloy may contain 75% by weight or more palladium, such as 80% by weight or more palladium, such as 85% by weight or more palladium and 25% by weight or less iridium, such as 20% by weight or less iridium, such as 15% by weight or less iridium.

It should be understood that the number of conductive terminal pins should not be limited. For instance, the feedthrough filter assembly may be unipolar (one), bipolar (two), tripolar (three), quadpolar (four), pentapolar (five), hexpolar (six), etc., and may extend through one or more additional passageways of the capacitor. In one embodiment, the capacitor 120 is a discoidal capacitor that has a generally cylindrical shape and only one conductive terminal pin is utilized through the discoidal capacitor. In other embodiments, the capacitor 120 may utilize one or more conductive terminal pins.

In some example embodiments, the feedthrough filter assembly also includes an RF pin. For instance, the RF pin may be an RF telemetry pin as generally employed in the art. Such pin may allow a physician to use a radio frequency interrogator to interrogate a patient sitting in a chair across the room while the physician is sitting conveniently at his or her desk.

In other example embodiments, the feedthrough filter assembly may include other pins that are not active conductive terminal pins or RF pins. For instance, such pins may be incorporated to provide mechanical stability or for providing a location for connection. Examples of such pins include, but are not limited to, ground pins. Ground pins may be connected (e.g., brazed) directly to the ferrule. In another embodiment, a ground pin may be employed that does not extend through the capacitor. For instance, such ground pin may be for externally grounding the capacitor via the ferrule and second termination surface of the capacitor.

Additionally, the feedthrough filter assembly 100 may also include an insulator 140. In general, the insulator 140 can be fixed to the ferrule 104. The insulator 140 can be utilized to conductively isolate a terminal pin 102 from the ferrule 104. In this regard, the insulator 140 may be a ceramic material, for example one having good insulating properties. For instance, the insulator 140 may be an alumina insulator or the like. For instance, the insulator 140 may be 99.9% alumina. Alternatively, the insulator 140 may be glass or the like.

In certain embodiments, the insulator 140 may also provide a sealing element. The sealing element may include a hermetic seal, which might be particularly useful in medical applications for protecting against body fluids, or an environmental seal, which might be particularly useful in protecting against dust, moisture, and other environmental factors. Thus, it should be understood that hermetic seals may not be required in all applications. However, when the insulator 140 provides a seal, the conductive terminal pins 102 may be installed into the insulator 140 using a material that provides a seal. In addition, the seal may also be formed between the insulator 140 and the ferrule 104. Further, such seal may also be formed between the insulator 140 and an RF pin when present. Such seal may be formed of a sealing material, such as hermetically sealing material or other material, including, but not limited to, epoxy-based materials (e.g., epoxy resins), silicone-based materials, urethane-based materials, polyurethane-based materials, elastomeric-based materials, and acrylic-based materials.

The feedthrough filter assembly may also include a resinous element 106 positioned above the capacitor 120 to seal the capacitor element within the feedthrough filter assembly 100. The resinous element 106 may be any form of resinous material suitable for sealing as known in the art, as described above. For instance, in certain example embodiments, the resinous element 106 may comprise epoxy resin. Similar to the insulator 140, the resinous element 106 may also provide a sealing element, such as a hermetic seal.

In certain embodiments, hermetic seals can be formed from a hermetically sealing material that is present through at least 30%, such as at least 40%, such as at least 50%, such as at least 60% of the thickness of the insulator and/or resinous element in the direction in which the conductive terminal pin extends. In addition, the width of the presence of the hermetically sealing material may be greater adjacent the insulative layer than the width at approximately a 50% thickness of the insulator.

Regarding the hermetic seal of the insulator 140, such hermetic seal can be provided using a hermetically sealing material as generally employed in the art. The hermetically sealing material may generally be formed from a noble material, such as silver, platinum, iridium, gold, and the like. In one embodiment, the hermetically sealing material may be formed from gold, such as a gold brazing. The gold brazing may be 99% by weight or more gold, such as 99.9% by weight or more gold, such as 99.99% by weight or more gold, such as 99.999% by weight or more gold. Aside from gold brazing, it should be understood that other materials, such as sealing glass, may also be employed as the hermetically sealing material.

In addition, the hermetic seal may also include metallization on the insulator. Such metallization may include an active layer and a barrier layer for protecting the active layer. For instance, the insulator may include a titanium/molybdenum metallization to provide a hermetic seal. For instance, titanium may be formed as an active layer followed by molybdenum as a barrier layer. In general, the molybdenum layer can protect the titanium layer from excessive oxidation prior to brazing and may act as a barrier material between the gold brazing material and the titanium layer. Such layers may allow for the brazing material, such as gold, to wet the insulator and form the hermetic seal. While titanium and molybdenum are mentioned, it should be understood that other metallization materials may also be employed. These may include titanium, niobium, chromium, zirconium, or vanadium as materials for the active layer with molybdenum, platinum, palladium, tantalum or tungsten as materials for the barrier layer. These layers may be formed by sputtering or other chemical vapor deposition techniques, laser or other physical vapor deposition techniques, vacuum evaporation, thick film application methods, plating, etc.

Regarding the hermetic seal of the resinous element 106, the hermetically sealing material may be a nonconductive resin. In one embodiment, such resin may be a thermosetting polymer. In particular, such resin may be an epoxy resin.

It should be understood by one of ordinary skill in the art that additional resin may be used throughout the feedthrough filter assembly based on the desired sealing characteristics and desired applications of the feedthrough filter assembly. In one embodiment, such additional resin may coat the hermetically sealing material present between the insulator and the conductive terminal pins. In another embodiment, the resin may coat the hermetically sealing material present between the insulator and the RF pin, when present.

For application, the thermosetting resin may be applied in a non-cured form. For instance, such resin may be in a liquid state or semi-solid state and may be applied to coat the hermetically sealing material. Furthermore, in one embodiment, the resin may be extended to coat not only the hermetically sealing material, but also some of the insulator. In one embodiment, the resin does not extend to cover the entire area over the insulator between two adjacent conductive terminal pins.

In certain example embodiments, the feedthrough filter assembly includes an insulative layer between the insulator and the capacitor. In addition, the conductive terminal pins may extend through the insulative layer, for instance in a non-conductive manner. In addition, the insulative layer may be in direct contact with the insulator. In one embodiment, the insulative layer includes a thermosetting polymer. For instance, the thermosetting polymer may include a polyimide.

In one embodiment, the insulative layer may be a laminated insulative layer. For instance, the laminated insulative layer may include a top layer, a middle layer, and a bottom layer opposite the top layer. The middle layer may include a conductive thermosetting polymer, such as a polyimide. Nevertheless, it should be understood that other conductive thermosetting polymers may also be employed. Meanwhile, the top layer and/or the bottom layer may comprise an adhesive layer. The adhesive layer may not necessarily be limited.

In other example embodiments, the feedthrough filter assembly may include a washer between the insulative layer and the feedthrough filter capacitor. For instance, the washer may surround the conductive terminal pin. In particular, each conductive terminal pin may include a washer surrounding the pin. The washer may be made from a conductive thermosetting polymer. For instance, the washer may be made from a polyimide. However, it should be understood that the present invention may be practiced without the aforementioned washer.

Furthermore, the feedthrough filter assembly may include wire bond pads. These pads may be attached by soldering, welding, brazing, thermal conductive polymer or the like. The wire bond pad can be made from any type of material known in the art. For instance, the wire bond pad may be made from materials including nickel, copper, steel and the like. The pad may also be formed from other materials such as tantalum, molybdenum, titanium, titanium alloys, rhodium, osmium, silver, silver alloys, vanadium, platinum, platinum alloys, niobium, stainless steel, tungsten, rhenium, zirconium, vanadium, ruthenium, etc. In addition, the wire bond pad may also be finished or plated. For instance, the wire bond pad may be gold plated.

The filter feedthrough assemblies can be employed in various applications. For instance, the feedthrough filter assemblies can be employed in those applications where it may be desirable to decouple and shield undesirable electromagnetic interference signals from the device. For instance, these may include implantable medical devices such as cardiac pacemakers, cardioverter defibrillators, neuro-stimulators, internal drug pumps, cochlear implants and other medical implant applications. In general, the housing for these materials includes a biocompatible metal which is electrically and mechanically coupled to the ferrule.

The filter feedthrough assemblies may also be employed in various non-medical related applications. For instance, filtered feedthrough assemblies may be utilized in industrial manufacturing, cell phones, laptops, wi-fi devices, Bluetooth devices, baby monitors, refrigerators, washing machines, air conditioners, microwaves, toaster ovens, electric blankets, heating pads, heaters, lamps, audio equipment, LED lighting, solar inverters, wind turbines, electric vehicles, motor devices, robotics, signal processing devices, base transceiver stations, and any products that may desire to smooth voltage and remove unwanted noise.

It should be understood by one of ordinary skill in the art that the feedthrough filter capacitor may be utilized in any device which desires to filter unwanted EMI as the feedthrough filter capacitor and conductive terminal pin prevent entrance of interference signals to the interior of the device. Thus, the conductive pin, in some embodiments, is generally isolated from the housing and the ferrule to maintain signal integrity and enhance filtering. However, in certain embodiments, if a ground pin is employed, then a conductive pin may be connected to the housing or ferrule to intentionally provide additional grounding.

These and other modifications and variations of the present invention may be practiced by those of ordinary skill in the art, without departing from the spirit and scope of the present invention. In addition, it should be understood that aspects of the various embodiments may be interchanged both in whole or in part. Furthermore, those of ordinary skill in the art will appreciate that the foregoing description is by way of example only, and is not intended to limit the invention further described in such appended claims.

What is claimed is:

1. A feedthrough filter assembly comprising:
a feedthrough filter capacitor including first and second sets of electrode plates, a passageway therethrough having a first termination surface conductively coupling the first set of electrode plates, and a second termination surface exteriorly coupling the second set of electrode plates;
a conductive ferrule adjacent to the feedthrough filter capacitor;
a solder film comprising solder and a film-forming flux, wherein the solder film conductively couples at least a portion of the second termination surface of the feedthrough filter capacitor to the ferrule; and
a conductive terminal pin extending through the passageway in conductive relation with the first set of electrode plates, and through the ferrule in non-conductive relation.

2. The feedthrough filter assembly of claim 1, wherein the solder comprises tin, lead, silver, copper, or an alloy thereof.

3. The feedthrough filter assembly of claim 1, wherein the film-forming flux comprises a water-soluble flux, rosin-based flux, no-clean flux, inorganic flux, gel-based flux, wax-based flux, or a combination thereof.

4. The feedthrough filter assembly of claim 3, wherein the film-forming flux comprises a wax-based flux.

5. The feedthrough filter assembly of claim 4, wherein the wax-based flux comprises a paraffin wax.

6. The feedthrough filter assembly of claim 1, wherein the solder film has a melting temperature of about 20 °C to about 100 °C.

7. The feedthrough filter assembly of claim 1, wherein the conductive ferrule comprises a biocompatible electrically conductive metal.

8. The feedthrough filter assembly of claim 7, wherein the biocompatible electrically conductive metal comprises titanium, niobium, aluminum, stainless steel, zirconium, tantalum, nickel, or an alloy thereof.

9. The feedthrough filter assembly of claim 1, wherein at least a portion of a bottom surface of the feedthrough filter capacitor is substantially flush with a surface of the conductive ferrule.

10. The feedthrough filter assembly of claim 1, further comprising a support structure configured inside of the conductive ferrule, wherein the support structure is in contact with at least a portion of a bottom surface of the feedthrough filter capacitor and the solder film.

11. The feedthrough filter assembly of claim 1, wherein the conductive terminal pin comprises platinum, gold, titanium, niobium, tantalum, palladium, iridium, or an alloy thereof.

12. The feedthrough filter assembly of claim 1, wherein the feedthrough filter capacitor is a discoidal capacitor.

13. The feedthrough filter assembly of claim 12, wherein the discoidal capacitor has a cylindrical shape, wherein the conductive terminal pin comprises one conductive terminal pin that extends through the passageway in conductive relation with the first set of electrode plates.

14. The feedthrough filter assembly of claim 1, further comprising one or more conductive terminal pins.

15. The feedthrough filter assembly of claim 1, further comprising an insulator fixed to the conductive ferrule for conductively isolating the conductive terminal pin from the conductive ferrule.

16. The feedthrough filter assembly of claim 15, wherein a sealing material is between the insulator and the conductive terminal pin.

17. The feedthrough filter assembly of claim 16, wherein the sealing material is a hermetically sealing material.

18. The feedthrough filter assembly of claim 16, wherein the sealing material is an epoxy resin.

19. A method for forming a feedthrough filter assembly, the method comprising:
disposing a filter feedthrough capacitor within a conductive ferrule, wherein the capacitor includes first and second sets of electrode plates, a passageway therethrough having a first termination surface conductively coupling the first set of electrode plates, and a second termination surface exteriorly coupling the second set of electrode plates;
disposing a solder film comprising a solder and a film-forming flux in contact with the filter feedthrough capacitor and the conductive ferrule;
conductively coupling the second termination surface of the filter feedthrough capacitor and the conductive ferrule.

20. The method of claim 19, further comprising heating the solder film to disperse the solder between the second termination surface of the filter feedthrough capacitor and the conductive ferrule.

21. The method of claim 20, further comprising removing the film-forming flux from the filter feedthrough capacitor after heating the solder film to disperse the solder between the second termination surface of the filter feedthrough capacitor and the conductive ferrule.

22. The method of claim 20, wherein the heating occurs at a temperature of about 20 °C to about 100 °C.

23. The method of claim 19, wherein the conductively coupling occurs by heating the solder to a temperature of from about 170 °C to about 350 °C.

24. The method of claim 19, further comprising extending a conductive terminal pin through the passageway.

25. The method of claim 19, wherein the solder film is formed through a process comprising:
mixing a powder, a solvent, and a film-forming flux to form a slurry;
forming the slurry to a predetermined shape; and
drying the solvent from the slurry to form the solder film.

26. The method of claim 25, wherein the slurry is formed to the predetermined shape by casting the slurry into a mold.

27. The method of claim 19, wherein the solder comprises tin, lead, alloy, silver, copper, or an alloy thereof.

28. The method of claim 19, wherein the film-forming flux comprises a water-soluble flux, rosin-based flux, no-clean flux, inorganic flux, gel-based flux, wax-based flux, or a combination thereof.

29. The method of claim 28, wherein the wax-based flux comprises a paraffin wax.
